(19) United States
(12) Patent Application Publication
(10) Pub. No.: US 2010/0315938 A1
(43) Pub. Date: Dec. 16, 2010

(54) LOW DISTORTION PACKAGE FOR A MEMS DEVICE INCLUDING MEMORY

(75) Inventors: Peter David Ascanio, Fremont, CA (US); Tom P. Frangesh, Campbell, CA (US)

Correspondence Address: FLIESLER MEYER LLP, 650 CALIFORNIA STREET, 14TH FLOOR, SAN FRANCISCO, CA, 94108, US

(73) Assignee: NANOCHIP, INC., Fremont, CA (US)

(21) Appl. No.: 12/192,006

(22) Filed: Aug. 14, 2008

(51) Int. Cl. G11B 9/00; H01L 23/48; B23P 17/04

(52) U.S. Cl. 369/126; 174/551; 29/592; G9B/9

(57) ABSTRACT

A package to receive a memory device including an electromagnetic motor comprises a body having a top surface and a bottom surface. Conductive leads extend through the body so that the conductive leads are at least partially exposed within the package. A base is connectable with the bottom surface of the body, and a lid is connectable with the top surface of the body. The base and the lid have substantially matched thermal expansion characteristics and provide magnetic flux return paths for the electromagnetic motor.

### CROSS-REFERENCE TO RELATED PATENT APPLICATIONS

This application incorporates by reference the following co-pending application:

U.S. patent application Ser. No. ______, entitled “Package with Integrated Magnets for Electromagnetically-Actuated Probe-Storage Device,” Attorney Docket No. NANO-01097US0, filed concurrently.

### BACKGROUND

Software developers continue to develop steadily more data intensive products, such as evermore sophisticated, and graphic intensive applications and operating systems. As a result, higher capacity memory, both volatile and non-volatile, has been in persistent demand. Add to this demand the need for capacity for storing data and media files, and the confluence of personal computing and consumer electronics in the form of portable media players (PMPs), personal digital assistants (PDAs), sophisticated mobile phones, and laptop computers, which has placed a premium on compactness and reliability.

Nearly every personal computer and server in use today contains one or more hard disk drives (HDD) for permanently storing frequently accessed data. Every mainframe and supercomputer is connected to hundreds of HDDs. Consumer electronic goods ranging from camcorders to digital data recorders use HDDs. While HDDs store large amounts of data, HDDs consume a great deal of power, require long access times, and require “spin-up” time on power-up. Further, HDD technology based on magnetic recording technology is approaching a physical limitation due to super paramagnetic phenomenon. Data storage devices based on scanning probe microscopy (SPM) techniques have been studied as future ultra-high density (>1 Tbit/in2) systems. There is a need for packaging to protect assemblies used to apply such techniques.

### BRIEF DESCRIPTION OF THE DRAWINGS

Further details of the present invention are explained with the help of the attached drawings in which:

FIG. 1 is a cross-sectional side view of an information storage device including a plurality of tips extending from corresponding cantilevers toward a movable media.

FIG. 2 is an exploded perspective view of the information storage device of FIG. 1.

FIG. 3 is an exploded perspective view of an embodiment of a package for housing an information storage device in accordance with the present invention.

FIGS. 4A-4F are perspective views illustrating progressive stages of fabrication of a body of an embodiment of a package for housing an information storage device in accordance with the present invention.

FIG. 5 is a cross-sectional perspective view of a portion of the body of FIG. 4B.

### DETAILED DESCRIPTION

Common reference numerals are used throughout the drawings and detailed description to indicate like elements; therefore, reference numerals used in a drawing may or may not be referenced in the detailed description specific to such drawing if the associated element is described elsewhere.

Information storage devices enabling potentially higher density storage relative to current ferromagnetic and solid state storage technology can include nanometer-scale heads, contact probe tips, non-contact probe tips, and the like capable of one or both of reading and writing to a media. High density information storage devices can include seek-and-scan probe (SSP) memory devices comprising cantilevers from which probe tips extend for communicating with a media using scanning-probe techniques. The cantilevers and probe tips can be implemented in a micro-electromechanical system (MEMS) and/or nano-electromechanical system (NEMS) device with a plurality of read-write channels working in parallel. Probe tips are hereinafter referred to as tips and can comprise structures that communicate with a media in one or more of contact, near contact, and non-contact mode. A tip need not be a protruding structure. For example, in some embodiments, a tip can comprise a cantilever or a portion of the cantilever.

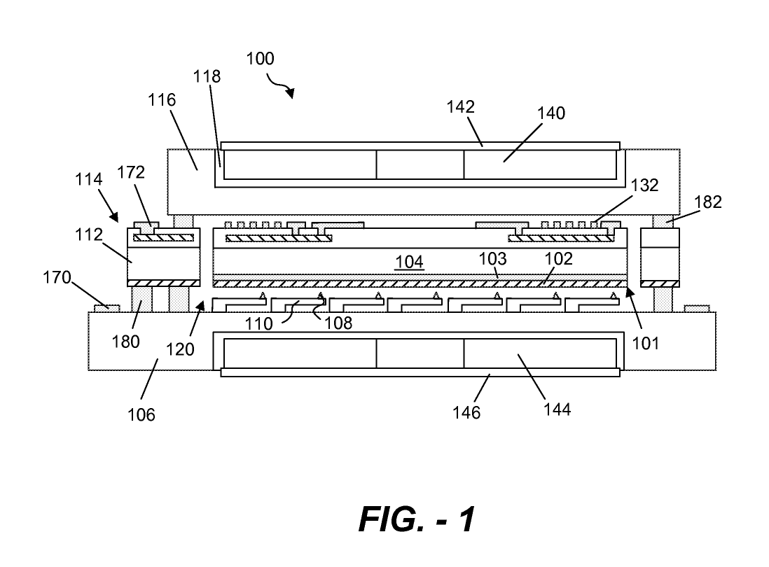

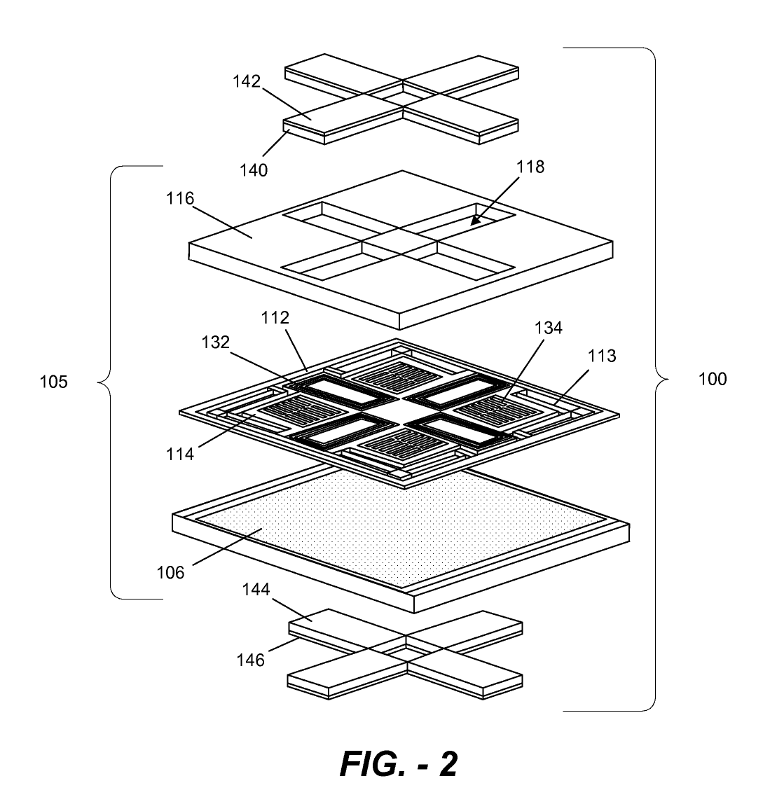

FIG. 1 is a simplified cross-section and FIG. 2 is an exploded perspective view of a system for storing information (also referred to herein as a memory device) 100 comprising a tip substrate 106 arranged substantially parallel to a media 101 disposed on a media platform 104. Cantilevers 110 extend from the tip substrate 106, and tips 108 extend from respective cantilevers 110 toward the surface of the media 101. The media 101 includes a recording layer 102 and a conductive layer 101 arranged between the recording layer 102 and the media platform 104. The recording layer 102 can comprise a chalcogenide material, ferroelectric material, polymeric material, charge-trap material, or some other manipulable material known in probe-storage literature. Embodiments of methods in accordance with the present invention can be applicable to multiple different recording layer materials and information storage techniques; however, methods in accordance with the present invention will be described hereinafter with particular reference to recording layers comprising ferroelectric materials.

A media substrate 114 comprises the media platform 104 suspended within a frame 112 by a plurality of suspension structures (e.g., flexures) 113. The media platform 104 can be urged in a Cartesian plane within the frame 112 by electro-magnetic motors comprising electrical traces 132 (also referred to herein as coils, although the electrical traces need not consist of closed loops) placed in a magnetic field so that controlled movement of the media platform 104 can be achieved when current is applied to the electrical traces 132. The media platform 104 is urged by taking advantage of Lorentz forces generated from current flowing in the coils 132 when a magnetic field perpendicular to the Cartesian plane is applied across the coil current path. A magnetic field is generated outside of the media platform 104 by a first permanent magnet 140 and second permanent magnet 144 arranged so that the permanent magnets 140,144 roughly map the range of movement of the coils 132. The permanent magnets 140,144 can be fixedly connected with a rigid or semi-rigid structure such as a flux plate 142,146 formed from steel, or some other material for acting as a magnetic flux return path and containing magnetic flux. As shown, the tip substrate 106 includes pockets 107 to receive permanent magnets 144. Optionally some small gap can exist between the tip substrate 106 and permanent magnets 144. Forming pockets 107 within the tip substrate 106 can reduce an overall thickness of the memory device 100; however, in other embodiments the tip substrate 106 need not include pockets 107. In such embodiments, the tip substrate 106 can be uniformly thinned, where overall thickness is a consideration. In other embodiments, a single magnet can be used to generate the magnetic field between two flux plates. In still other embodiments, the media platform 104 can be urged within the frame 112 by some other mechanism, such as thermal actuators, piezoelectric actuators, etc. A cap 116 can be bonded with the media substrate 114 and the media substrate 114 can be bonded with the tip substrate 106 to seal the media platform 104 within a cavity 120 between the cap 116 and tip substrate 106. Solder layers 180,182 can be formed suitable for substrate bonding. The sealing is, preferably, near-hermetic or hermetic. Optionally, nitrogen or some other passivation gas, at atmospheric pressure or at some other desired pressure, can be introduced and sealed in the cavity 120. The memory device 100 can communicate electrically with structures separate from the memory device 100 by way of bond pads 170,172 electrically connected with circuitry of the tip substrate 106 and/or media substrate 114. As shown, the cap 116 also includes pockets 118 to receive permanent magnets 140. Including pockets 118 in the cap 116 allows the average thickness of the cap 116 to be increased, improving resistance to deformation due to external forces. Preferably some small gap exists between the cap 116 and permanent magnets 140 to allow a small amount of relative movement, as described in U.S. Ser. No. 60/989,715, entitled “ENVIRONMENTAL MANAGEMENT OF A PROBE STORAGE DEVICE.” In other embodiments, the cap 116 need not include pockets 118, for example where thickness of the memory device without pockets 118 is within a defined specification.

Coarse servo control of a position of the media platform 104 within the frame 112 can be achieved through the use of capacitive sensors. The capacitive sensors partly comprise electrodes 134 associated with the media platform 104 and one or more electrodes (not shown) associated with a structure held static relative to the movable media platform 104, such as the cap 116. The electrodes are arranged to at least partially overlap such that relative movement between the cap 116 and media platform 104 is detectable by changes in capacitance. Alternatively, coarse servo control of the media platform 104 can be achieved using some other technique and device, such as Hall-effect sensors sensitive to magnetic field, thermal sensors to detect heat sources, etc.

Embodiments of packages and methods of packaging in accordance with the present invention can be applied to support memory devices such as described above. A package and method of packaging preferably provides resistance to external forces such as shocks, compression, decompression, submersion, and other trauma or invasion experienced by electronic devices in typical usage. It is anticipated that packages and methods of packaging described herein will provide satisfactory performance at a satisfactory unit cost.

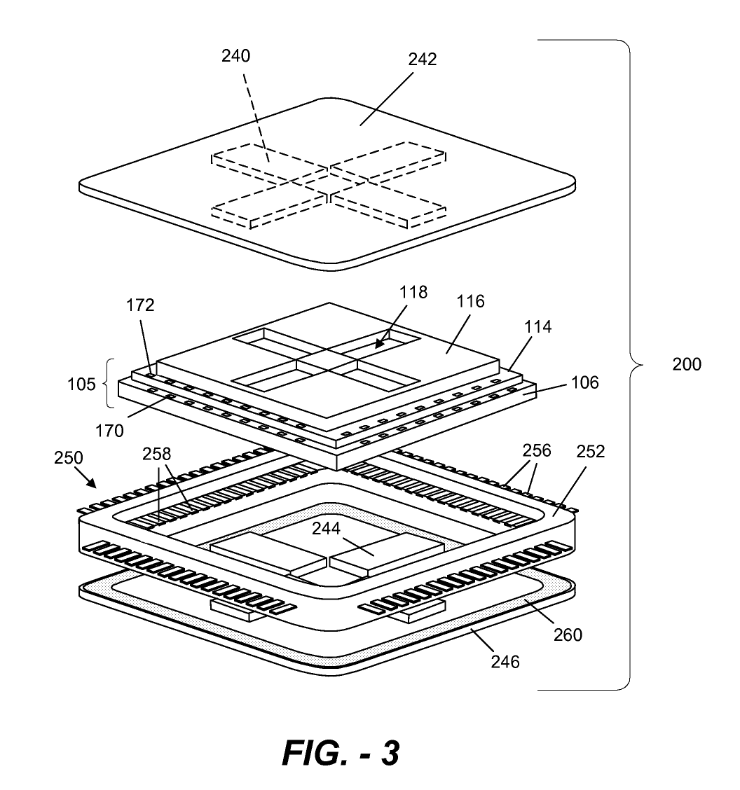

Typical packages and packaging techniques include wiring microchip bond pads to a leadframe, followed by encapsulation of the microchips in epoxy. After molding, the encapsulated microchips are mechanically separated from frame rails and the parts of the frame protruding from the Package become the package leads. FIG. 3 is an exploded perspective view of a memory device 200 and an embodiment of a package in accordance with the present invention. The package includes a body 250 within which is nested a stack 105 comprising the tip substrate 106, the media substrate 114, and the cap 116. The body 250 can be fabricated from a moldable material such as plastic. In a preferred embodiment, the body 250 can be fabricated from liquid crystal polymer (LCP). LCP has acceptable mechanical strength at high temperatures, extreme chemical resistance, inherent flame retardancy, and good weatherability. In other embodiments, the body 250 can comprise some other thermoplastic, such as polyetheretherketone (PEEK) or polycarbonate. In still other embodiments, the body can comprise some other material that is shapeable and provides adequate performance, for example a ceramic such as silicon carbide. The stack 105 is nested within the body 250 between a base and a lid that supplant the flux plate of the memory device. The memory device of FIGS. 1 and 2, and MEMS and NEMS in generally, include moving parts that may be vulnerable to external forces including torsion forces resulting from impacts, vibration, or other physical stress, or alternatively environmental factors such as compression/decompression due to changes in pressure and material expansion/contraction due to changes in temperature. Torsion forces, for example, can cause bending of the package, and by extension bending of the memory device. Bending of the memory device can urge cantilevers and tip against the media surface, can stress suspension structures, and may (or may not) result in damage to the cantilevers, tips and/or media. Embodiments of packages in accordance with the present invention can comprise a base and lid fabricated from the same material, or fabricated from materials having similar material properties, particularly similar thermal expansion properties. Further the base and lid can have substantially similar thicknesses. Preferably, the base and lid can be substantially the same structure. By matching the structures, bending caused by thermal expansion of the package can be reduced. Alternatively, the lid and base can be fabricated from different materials to have thicknesses that generally offset a difference in thermal expansion of the differing materials. Preferably, the base and the lid are fabricated from a material that acts as a magnetic flux return path, thereby containing magnetic flux. By acting as a magnetic flux return path, the base and lid can supplant the flux plates of FIGS. 1 and 2, reducing an overall thickness of the package. In this way, embodiments of packages in accordance with the present invention can provide a lid and base that both generally isolates the memory device from an external environment and is a functional component of the memory device.

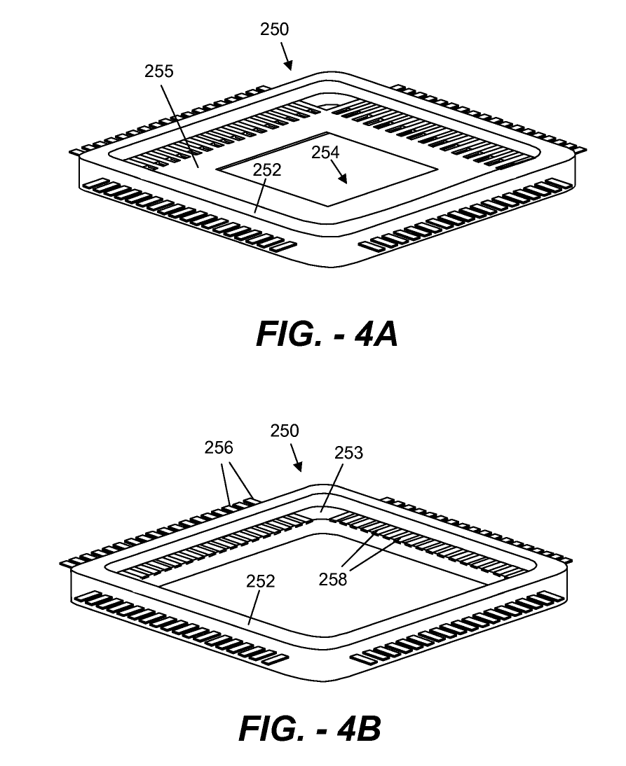

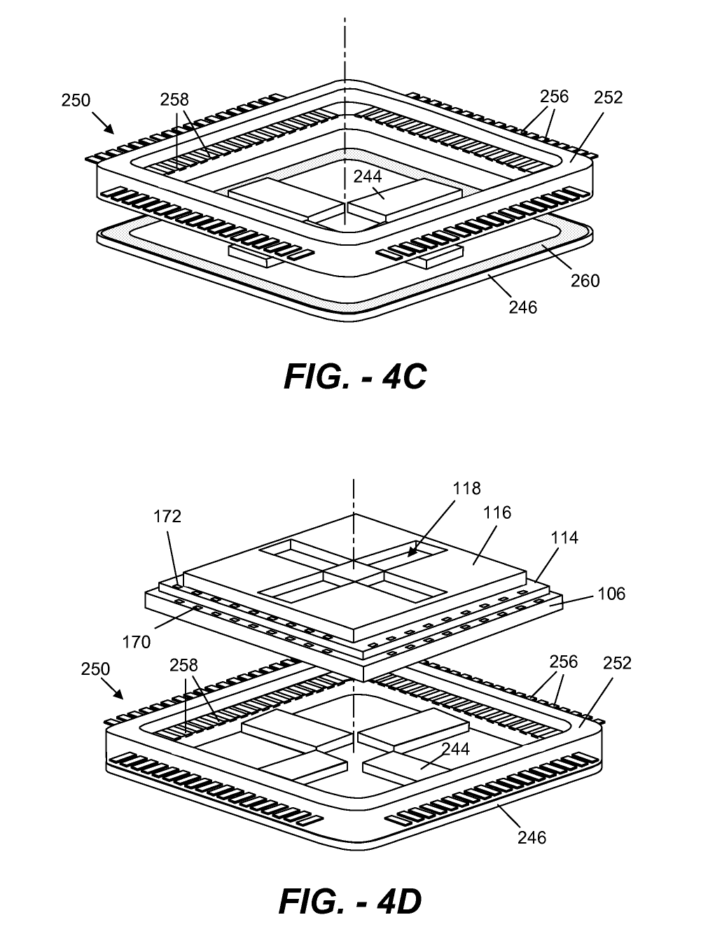

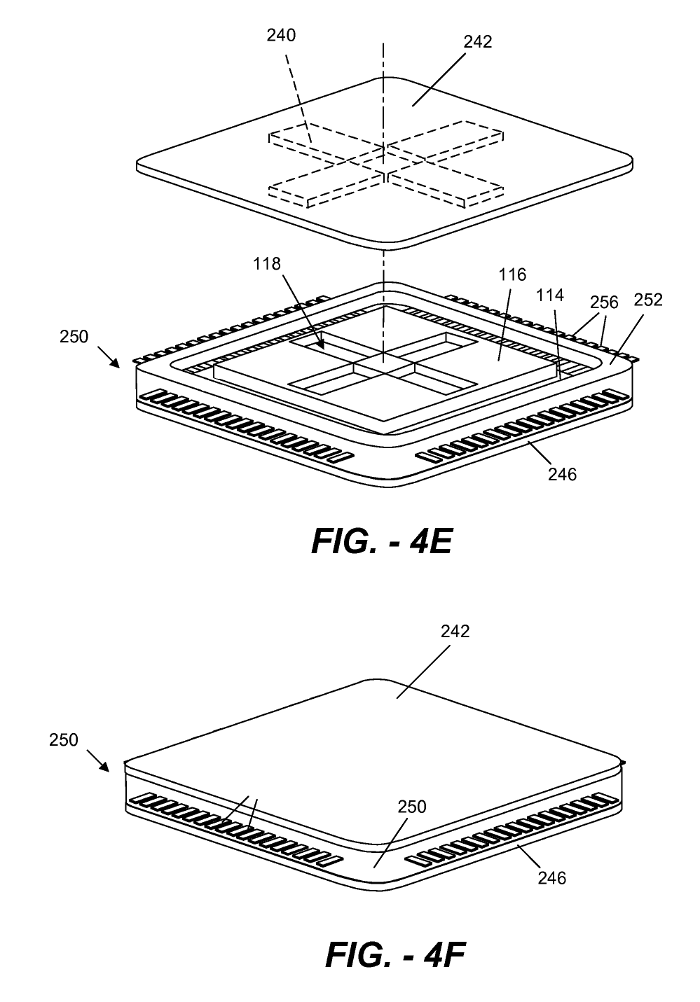

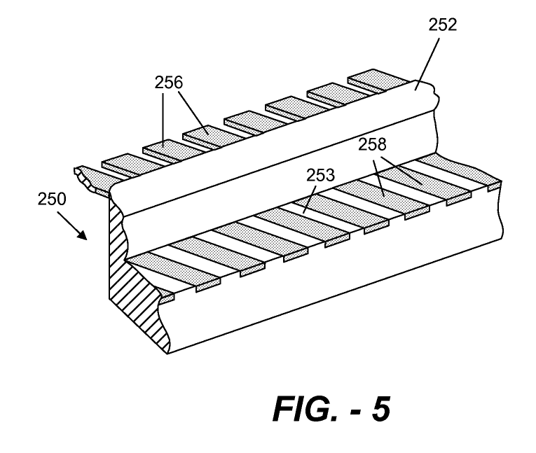

FIGS. 4A and 4B are perspective views illustrating progressive stages of an embodiment of a method to fabricate a body of a package in accordance with the present invention. A leadframe 254 is a metal frame to which microchips are attached during the package assembly process. A leadframe is typically (though not necessarily) a long metal frame with positions for multiple discrete microchips. While leadframes can have myriad different shapes and configurations, a leadframe for use with preferred embodiments conforms to a standard defined by the JEDEC Solid State Technology Association. Such a leadframe 254 can include repeating structures connected by frame rails (not shown) and mechanically separable. For example, the leads 256 of the leadframe 254 can be connected with a frame rail. FIG. 4A illustrates a leadframe 254 with a set of leads separated from a frame rail; however, successive fabrication steps are preferably (though not necessarily) performed prior to separation of the leadframe 254 from adjacent leadframes.

Referring to FIG. 4A, the body 250 is molded (or otherwise formed) onto the leadframe 254 with the body 250 encapsulating individual leads 256 of the leadframe 254 from where the leads 256 enter the package from the exterior and continues full four-sided lead encapsulation through an outer portion of the body 252. As shown in FIG. 4B, and more particularly in the magnified cut-away view of FIG. 5, the encapsulation continues on only three sides of a given lead through an inner portion of the body 253 which inner portion forming a stepped portion of the package exposing an open face 258 of the leads where bond wires will terminate. The leads continue to the interior of the package with no encapsulation, and may be joined together on the leadframe at a central support (also referred to as a dam) 255 that provides stability to the leads 256 during separation (e.g., by mechanical separation). Referring to FIG. 4B, after the body 250 is formed, the leads are separated from the central support 255 of the leadframe 254. For example, a die punch can be used to remove the central support 255 so that the leads are trimmed flush with, or close to, the inner vertical surface of the body 253. Current packaging technology typically includes molding plastic directly over a die or microchip and a lead frame. Embodiments of packages and methods of packaging in accordance with the present invention can comprise forming a body of a package so that a space within the body is accessible.

Referring to FIG. 4C, a first metallic piece 246 whose alloy and thickness are chosen for suitable application properties is attached onto the bottom face of the body 250, forming a base for the package. For a package housing the memory device 200 of FIG. 3 (generally resembling the memory device 100 described above) the first metallic piece 246 can supplant a flux plate, and therefore should provide satisfactory confinement of the magnetic flux associated with the magnets 240,244 of the memory device 200. Further, the first metallic piece 246 can comprise a material sufficiently rigid to resist deformation from external forces such as compressive (and decompressive) forces. For example, the first metallic piece 246 can comprise a low expansion material such as an iron-nickel alloy (e.g., alloy 42™, alloy 4750™) or steel. Such a material can have additional benefits, for example high heat dissipation for improved cooling of an enclosed microchip. Further, such a material can provide at least some protection or isolation from electromagnetic interference (EMI). Finally, depending on circuitry requirements, the base may be modified as required to accommodate multi-chip-module packaging.

Attachment of the first metallic piece 246 and the body 250 can be accomplished through use of an adhesive 260, or alternatively by way of thermal bonding, ultrasonic bonding, snap fitting, mechanical fastening, or other suitable means. In some embodiments, a set of magnets 244 associated with the electro-magnetic motors of the memory device 200 can be fixedly connected with the first metallic piece 246 prior to attachment of the first metallic piece 246 to the body 250. Securing the first metallic piece 246 prior to attachment can simplify manufacturing and further define a structure that can be used as a base or lid; however, in other embodiments, the first metallic piece 246 subsequent to attachment of the first metallic piece 246 to the body 250, while in still other embodiments the package may not include a set of magnets connected with the first metallic piece 246. As noted above use of a base and lid having identical structure can minimize bending affects of the package on the die.

As shown FIG. 4D, once the first metallic piece 246 is attached to the body 250, the stack 105 is positioned within the package. In an embodiment, the stack 105 can be attached to the set of first metallic piece 246 by a silicone adhesive. A silicone adhesive is a soft adhesive that can be used to support the stack and at least partially isolate the stack from external impacts. In other embodiments, some other binding agent or technique can be used to fixedly associate the stack 105 with the set of magnets 244. In still other embodiments, a structure can be positioned between the set of first metallic piece 246 and the stack 105. Although the stack is shown attaching to the set of first metallic piece 246 after the first metallic piece 246 is attached to the body 250, in other embodiments the steps of packaging can be performed in opposite order, with the stack 105 attaching to the first metallic piece 246 prior to attaching the first metallic piece 246 to the body 250. In still other embodiments, the stack 105 can be attached to the set of magnets 244 received within the pockets 107, or an intervening structure between the set of magnets 244 and the pockets 107.

After positioning the stack 105 in the package, wire bonding is performed between bond pads 170,172 of the stack 105 and the exposed open face 258 of the leads. Referring to FIGS. 4E and 4F, a second metallic piece 242 whose alloy and thickness are chosen for suitable application properties is attached onto the bottom face of the body 250, forming a lid for the package. As with the first metallic piece, 246, the second metallic piece 242 can supplant a flux plate, and therefore should provide satisfactory confinement of the magnetic flux associated with the magnets 240,244 of the memory device 200. Further, the second metallic piece 242 can comprise a material sufficiently rigid to resist deformation from external forces such as compressive (and decompressive) forces. For example, the second metallic piece 242 can comprise a low expansion material such as alloy 42, alloy 4750, or steel. As mentioned above, such a material can have additional benefits, for example high heat dissipation for improving cooling of an enclosed microchip. Further, such a material can provide at least some protection or isolation from electromagnetic interference (EMI). Finally, depending on circuitry requirements, the base may be modified as required to accommodate multi-chip-module packaging. A set of magnets 240 associated with the electro-magnetic motors of the memory device 200 can be fixedly connected with the second metallic piece 246 prior to attachment of the second metallic piece 246 to the body 250. Attachment of the second metallic piece 246 and the body 250 can be accomplished through use of an adhesive 260, or alternatively by way of thermal bonding, ultrasonic bonding, snap fitting, mechanical fastening or other suitable means. When positioning the second metallic piece 246, the associated set of magnets 240 are received within the pockets 118. Preferably, some small gap can exist between the cap 116 and the set of magnets 240 to increase manufacturing tolerances, and to allow some slight relative movement between the structures resulting from external forces applied to the package. Prior to attaching the second metallic piece 246 the space within the package can optionally be evacuated, filled with an inert or passivation gas. Although not preferred, in still other embodiments the memory device can be encapsulated, for example by filling the space in the package with a thermoplastic so that the structures are rigidly retained.

If the leadframe 254 is still connected with other leadframes, the leadframe 254 can be mechanically separated. For example, a punch or die can be used to trim all of the leads to the specified length and remove the package from the leadframes. The package housing the system 200 can then be electrically tested. The package housing the system 200 may be left as a flat pack, or the leads may be formed to create a surface mounting or thru-board device, before or after electrical test. While the package of FIG. 4F is shown as a flat pack, in other embodiments the leads can conform to different interconnect configurations. For example, the leads can be bent and follow along the outer surface of the body.

In light of the teachings provided herein, one of ordinary skill in the art will appreciate the myriad variations in shape and materials of the package and steps of the method of packaging described above. It is believed that embodiments of the package can provide reduced cost relative to existing packages (the package of FIG. 4F is estimated to cost $2 compared with a typical ceramic package cost of $20) and can provide improved heat dissipation, magnetic conduction, and EMI shielding. Packages and methods of packaging in accordance with the present invention concept allow for many shapes, sizes, lead counts, and configurations, including multi-chip modules (MCMs).

While embodiments of packages in accordance with the present invention have been described with specific reference to memory devices, one of ordinary skill in the art will appreciate, upon reflecting on the teaches provided herein, that such embodiments can benefit other MEMS and NEMS devices by providing a package with reduced distortion. Embodiments in accordance with the present invention are not intended to be limited to memory devices, but rather are intended to applied to any device which can benefit from a package with reduced distortion.

The foregoing description of the present invention has been presented for purposes of illustration and description. It is not intended to be exhaustive or to limit the invention to the precise forms disclosed. Many modifications and variations will be apparent to practitioners skilled in this art. The embodiments were chosen and described in order to best explain the principles of the invention and its practical application, thereby enabling others skilled in the art to understand the invention for various embodiments and with various modifications as are suited to the particular use contemplated. It is intended that the scope of the invention be defined by the following claims and their equivalents.

1. A package to receive a microelectromechanical system comprising:
a body having a top surface and a bottom surface;
a plurality of conductive leads extending through the body so that the plurality of conductive leads are at least partially exposed within the package;
a base connectable with the bottom surface;
a lid connectable with the top surface;
wherein the base and the lid have substantially matched thermal expansion characteristics; and
wherein the base and the lid are magnetic flux return paths for the electromagnetic motor.

2. The package of claim 1, wherein the body further comprises a moldable material.

3. The package of claim 2, wherein the moldable material is a thermoplastic.

4. The package of claim 2, wherein the moldable material is liquid crystal polymer.

5. The package of claim 1, wherein the base and the lid further comprises a metal alloy.

6. The package of claim 5, wherein the metal alloy is an iron-nickel alloy.

7. The package of claim 5, wherein the metal alloy is steel.

8. The package of claim 1, wherein the base is connectable with the bottom surface by an adhesive and the lid is connectable with the top surface by an adhesive so that the package is near-hermetically sealed.

9. The package of claim 1, wherein the base is connectable with the bottom surface by one or more of thermal bonding, ultrasonic bonding and snap fitting, and the lid is connectable with the top surface by one or more of thermal bonding, ultrasonic bonding and snap fitting.

10. The package of claim 1, further comprising one or more magnets fixedly connected with one or both of the base and the lid.

11. A system to storing information comprising:
a stack including:
a media substrate including a movable media in which indicia is formed;
a tip substrate connected with the media substrate and including a plurality of tips extending from the tip substrate;
wherein one or more of the tips is connectable with the media to detect the indicia;
a cap connected with the media substrate so that the movable media is arranged between the cap and the tip substrate;
an electromagnetic motor to controllably move the movable media;
a package to receive the stack including:
a body having a top surface and a bottom surface;
a plurality of conductive leads extending through the body so that the plurality of conductive leads are at least partially exposed within the package;
a base connectable with the bottom surface;
a lid connectable with the top surface;
wherein the base and the lid have substantially matched thermal expansion characteristics; and
wherein the base and the lid are magnetic flux return paths for the electromagnetic motor.

12. The package of claim 11, wherein the body further comprises a moldable material.

13. The package of claim 12, wherein the moldable material is a thermoplastic.

14. The package of claim 12, wherein the moldable material is liquid crystal polymer.

15. The package of claim 11, wherein the base and the lid further comprises a metal alloy.

16. The package of claim 15, wherein the metal alloy is an iron-nickel alloy.

17. The package of claim 15, wherein the metal alloy is steel.

18. A method to form a package to receive a memory device including an electromagnetic motor comprising:
molding a body on a leadframe so that a plurality of leads extend through the body and are accessible from either side of the body;
trimming the leadframe;
fixedly connecting a base to the body, the base being comprised of a material providing a magnetic flux return path;
fixedly connecting the memory device to the base;
wire bonding the plurality of leads to bond pads of the memory device;
fixedly connecting a lid to the body, the lid being comprised of a material providing a magnetic flux return path and having thermal expansion characteristics substantially similar to the base.

19. The method of claim 18, wherein molding a body on a leadframe further comprises molding a liquid crystal polymer on a leadframe.

20. The method of claim 18, further comprising:
fixedly connecting one or more magnets to the base prior to fixedly connecting the base to the body; and
fixedly connecting one or more magnets to the lid prior to fixedly connecting the lid to the body.
